(19) United States
(12) Patent Application Publication
(10) Pub. No.: US 2016/0352072 A1
(43) Pub. Date: Dec. 1, 2016

(54) MONOLITHIC TUNABLE TERAHERTZ RADIATION SOURCE USING NONLINEAR FREQUENCY MIXING IN QUANTUM CASCADE LASERS

(71) Applicant: BOARD OF REGENTS, THE UNIVERSITY OF TEXAS SYSTEM, Austin, TX (US)

(72) Inventors: Mikhail BELKIN, Austin, TX (US); Seungyong JUNG, Austin, TX (US); Karun VIJAYRAGHAVAN, Austin, TX (US)

(73) Assignee: Board of Regents, The University of Texas System, Austin, TX (US)

(21) Appl. No.: 15/116,823

(22) PCT Filed: Feb. 4, 2015
(86) PCT No.: PCT/US2015/014371

§ 371 Date: Aug. 4, 2016

Related U.S. Application Data
(60) Provisional application No. 61/935,400, filed on Feb. 4, 2014.

(51) Int. Cl. H01S 5/06; G02F 1/35; H01S 5/0625; H01S 5/34; H01S 5/343

(52) U.S. Cl. CPC H01S 5/0604; H01S 5/3401; H01S 5/34306; H01S 5/06258; G02F 1/3534; G02F 2203/13

(57) ABSTRACT

A terahertz difference-frequency generation quantum cascade laser source that provides monolithic, electrically-controlled tunable terahertz emission. The quantum cascade laser includes a substrate, a lower cladding layer positioned above the substrate and an active region layer with optical nonlinearity positioned on the lower cladding layer. The active region layer is arranged as a multiple quantum well structure. One or more feedback gratings are etched into spatially separated sections of the cladding layer positioned on either side of the active region. The periodicity of each grating section determines the mid-infrared lasing frequencies. The grating sections are electrically isolated from one another and biased independently. Tuning is achieved by changing a refractive index of one or all of the grating sections via a DC current bias thereby causing a shift in the mid-infrared lasing frequency. In this manner, a monolithic, electrically-pumped, tunable THz source is achieved.

### RELATED APPLICATIONS

This application claims priority, under 35 U.S.C. 371, to International patent application PCT/US15/14371, “Method and Apparatus for a Monolithic Tunable Terahertz Radiation Source Using Nonlinear Frequency Mixing in Quantum Cascade Lasers,” filed Feb. 4, 2015, which claims priority to,

U.S. Provisional Patent Application Ser. No. 61/935,400, “Method and Apparatus for a Monolithic Tunable Terahertz Radiation Source Using Nonlinear Frequency Mixing in Quantum Cascade Lasers,” filed Feb. 4, 2014,

Both of which are incorporated by reference herein in their entirety.

### GOVERNMENT INTERESTS

This invention was made with government support under Grant nos. ECCS1150449 and ECCS0925217 awarded by the National Science Foundation and Grant no. N66001-12-1-4241 awarded by the Space and Naval Warfare Systems Center (SSC) Pacific. The government has certain rights in the invention.

### BACKGROUND

The present invention relates generally to tunable terahertz quantum cascade lasers, and more particularly to a monolithic tunable terahertz radiation source using nonlinear frequency mixing in quantum cascade lasers.

Mass-producible semiconductor sources of tunable coherent terahertz (THz) radiation in the 1-5 THz spectral range are highly desired for sensing, spectroscopy and imaging applications. Besides p-doped Germanium lasers that require strong magnetic fields and low-temperature cryogenic cooling for operation, quantum cascade lasers (QCLs) are the only electrically-pumped semiconductor sources that demonstrate operation in this entire spectral range. Narrowband THz emission has been demonstrated in both THz QCLs and THz sources based on intracavity difference-frequency generation (DFG) in mid-infrared QCLs (THz DFG-QCLs). The latter is the only technology that results in electrically-pumped monolithic semiconductor sources operable at room-temperature in the entire 1-5 THz range.

Single-frequency operation with wide continuous tunability is an essential requirement for THz sources for many sensing and spectroscopy applications. Spectral tuning of THz DFG-QCLs from 1.25 to 5.9 THz has recently been achieved using a diffraction grating in an external cavity setup. However, external cavity tunable laser systems are bulky, have moving parts, and require precise alignment of optical components. Monolithic (i.e., no moving parts or external components required) electrically-tunable THz sources would be better suited for many applications owing to their compactness, propensity for mass-production, and high reliability due to the lack of mechanical components.

The tuning range of monolithic single-mode THz QCLs and THz DFG-QCL sources demonstrated so far is limited to below 30 GHz. Hence, there is not a means for designing monolithic THz DFG-QCL tuners that do not have any moving parts and can be electrically tuned over a wide tuning range.

### BRIEF SUMMARY

In one embodiment of the present invention, a terahertz difference-frequency generation quantum cascade laser source comprises a quantum cascade laser comprising a substrate. The quantum cascade laser further comprises a lower cladding semiconducting layer positioned above the substrate. The quantum cascade laser additionally comprises an active region layer with optical nonlinearity, where the active region layer is positioned on the lower cladding semiconductor layer, and where the active region layer is arranged as a multiple quantum well structure with optical nonlinearity for terahertz generation. Furthermore, the quantum cascade laser comprises an upper cladding semiconducting layer positioned on the active region layer. Additionally, the quantum cascade laser comprises two or more mid-infrared feedback gratings etched into spatially separated sections of the lower or upper cladding semiconducting layers, where the two or more mid-infrared feedback gratings are positioned along a length of a laser cavity, and where mid-infrared lasing frequencies are determined by a periodicity of the two or more mid-infrared feedback gratings. The two or more mid-infrared feedback gratings are electrically isolated from one another and are biased independently to turn on or off the mid-infrared lasing. Furthermore, tuning is achieved by changing a refractive index of one or all of the two or more mid-infrared feedback gratings via a DC current bias thereby causing a shift in a mid-infrared lasing frequency, where a change in the mid-infrared lasing frequency translates to turning of terahertz radiation. The quantum cascade laser generates terahertz radiation via infrared difference-frequency generation and simultaneously operates at multiple mid-infrared frequencies. Additionally, the quantum cascade laser source is designed with a modal phase matching scheme or a Cherenkov phase matching scheme to extract terahertz radiation.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE DRAWINGS

A better understanding of the present invention can be obtained when the following detailed description is considered in conjunction with the following drawings, in which:

FIG. 1A illustrates a schematic of a Cherenkov THz DFG-QCL source in accordance with an embodiment of the present invention;

FIG. 1B is a graph of the room temperature emission spectrum (blue) for a 2.7 mm cavity length device in accordance with an embodiment of the present invention;

FIG. 1C illustrates a waveguide cross-section for Cherenkov DFG-QCL lasers in accordance with an embodiment of the present invention;

FIG. 2A illustrates the device configuration for low-frequency mid-IR pump tuning as well as the dual-color emission spectra for different DC bias currents applied to the back section in accordance with an embodiment of the present invention;

FIG. 2B illustrates the device configuration for high-frequency mid-IR pump tuning, where the back section is unbiased while the front section is biased through a bias tree with both variable DC current (0 mA-300 mA) and 1.3×Iₜₕ (2.4 A) current pulses in accordance with an embodiment of the present invention;

FIG. 3A shows the details on the tuning behavior of the two mid-IR pump frequencies as a function of dissipated DC power, calculated as I_{DC}×V_{DC}, where I_{DC} and V_{DC} are the values of DC current and voltage applied to the grating sections in accordance with an embodiment of the present invention;

FIG. 3B shows the details on the tuning behavior of the two mid-IR pump frequencies as a function of dissipated DC power, calculated as I_{DC}×V_{DC}, where I_{DC} and V_{DC} are the values of DC current and voltage applied to the grating sections in accordance with an embodiment of the present invention;

FIG. 4A illustrates the spectra of tunable THz emission measured from the laser in accordance with an embodiment of the present invention;

FIG. 4B illustrates the details of the tuning behavior of THz emission frequency in accordance with an embodiment of the present invention;

FIG. 5A illustrates the light output-current and current-voltage characteristics of the mid-IR pumps of the device of the present invention measured without any DC bias in accordance with an embodiment of the present invention;

FIG. 5B illustrates the peak THz power and mid-IR-to-THz conversion efficiency measured under the same operating conditions as in FIG. 5A in accordance with an embodiment of the present invention; and

FIG. 6 depicts the quantum cascade laser of FIG. 1 being modified by including an independently controlled tuning element positioned on each grating section in accordance with an embodiment of the present invention.

### DETAILED DESCRIPTION

In the following description, various embodiments are described. For purposes of explanation, specific configurations and details are set forth in order to provide a thorough understanding of the embodiments. Well-known features may be omitted or simplified in order not to obscure the embodiment being described.

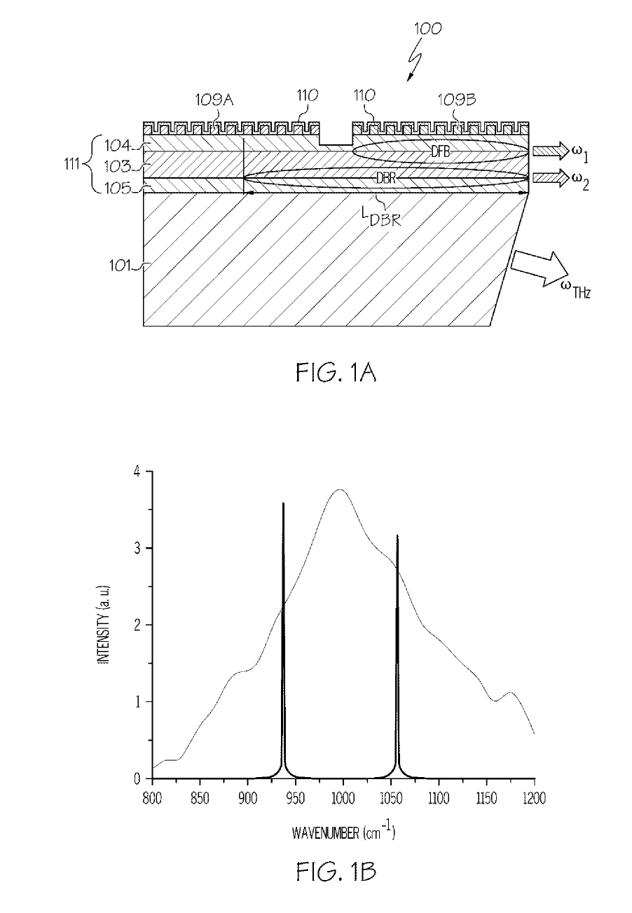

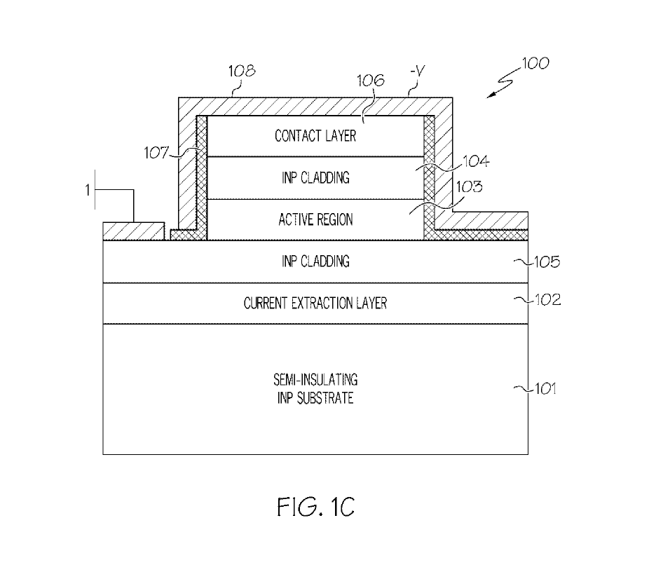

THz tuning in the difference-frequency generation (DFG) process ω_{THz}=ω₁−ω₂, where ω₁>ω₂, can be achieved by changing mid-infrared (mid-IR) pump frequencies, ω₁ or ω₂. Since a small fractional shift in mid-IR pump frequency translates into a large fractional change of THz emission frequency, this approach leads to monolithic THz semiconductor sources with an extremely wide tuning range as discussed further below. To independently control two mid-IR pump frequencies, the device of the present invention includes two independently-biased distributed grating sections for each mid-infrared pump wavelength. By controlling the DC current through these sections, one can electrically tune ω₁ or ω₂ via thermally changing the refractive index of the section. The mid-IR pump frequencies in the devices of the present invention can only be red shifted with an increase of DC current; however, THz emission frequency is given by the difference of the two mid-IR frequencies and thus can be both blue and red shifted depending on the choice of the mid-IR frequency to tune as discussed further below. The operating principle of such THz sources is depicted in FIGS. 1A-1C.

FIG. 1A illustrates a schematic of a Cherenkov THz DFG-QCL source in accordance with an embodiment of the present invention. FIG. 1B is a graph of the room temperature emission spectrum (blue) for a 2.7 mm cavity length device. FIG. 1C illustrates a waveguide cross-section for Cherenkov DFG-QCL lasers in accordance with an embodiment of the present invention.

Referring to FIGS. 1A-1C, a broadband THz DFG-QCL source includes a quantum cascade laser 100, which includes a substrate 101 that may be comprised of a III-V semiconductor compound, such as InP. In one embodiment, substrate 101 is formed of semi-insulating, undoped or very low doped (concentration of dopant <10¹⁶ cm⁻³) indium phosphide. In one embodiment, substrate 101 has a thickness between 100 μm and 3,000 μm. In another embodiment, substrate 101 has a thickness of less than 100 μm or more than 3,000 μm.

Furthermore, quantum cascade laser 100 includes a doped current extraction semiconductor layer 102 positioned on substrate 101. Furthermore, quantum cascade laser 100 includes an active region layer 103 surrounded by waveguide semiconducting clad layers 104, 105 (clad layer 104 is identified as “up clad” in FIG. 1A and clad layer 105 is identified as “low clad” in FIG. 1A), where clad layer 105 is positioned on top of current extraction semiconductor layer 102. As will be discussed further herein, current extraction layer semiconductor layer 102 is used for lateral current extraction from active region layer 103 in the Cherenkov waveguide configuration. In one embodiment, current extraction layer 102 and waveguide clad layer(s) 105 are the same layer. Waveguide clad layers 104, 105 are disposed to form a waveguide structure to guide mid-infrared light by which terahertz radiation generated in active region layer 102 is emitted by laser 100. Additionally, a contact layer 106 is formed on top of the upper side of waveguide clad layer(s) 104 as shown in FIG. 1C. Furthermore, an insulation layer 107, such as SiₓN_{y} (e.g., Si₃N₄), is deposited over contact layer 106, cladding layers 104, 105 and active region 103 as illustrated in FIG. 1C. In another embodiment of the present invention, the silicon nitride of insulation layer 107 is replaced by semi-insulating InP to form a buried heterostructure waveguide. Additionally, contact layer 108 is formed on top of contact layer 106 and insulation layer 107 as illustrated in FIG. 1C.

Active region layer 102 includes semiconductor layers that generate light of a predetermined wavelength (for example, light in the mid-infrared wavelength range) and provide giant optical nonlinearity for terahertz difference-frequency generation by making use of intersubband transitions in a quantum well structure. In the present embodiment, in correspondence to the use of an InP substrate 101 as the semiconductor substrate, active region layer 102 is arranged as an InGaAs/InAlAs multiple quantum well structure that uses InGaAs in quantum well layers and uses InAlAs in quantum barrier layers.

Specifically, active region layer 102 is formed by multiple repetitions of a quantum cascade structure in which the light emitting layers and electron injection layers are laminated. The number of quantum cascade structure repetitions in the active region is set suitably and is, for example, approximately 10-80 for mid-infrared QCLs and THz DFG-QCLs.

In one embodiment, active region layer 102 includes one or more different quantum cascade sections designed for a broad mid-IR spectral gain bandwidth spanning anywhere from 0.1 THz-10 THz.

Two mid-IR pumps at frequencies ω₁ and ω₂ propagate in the laser waveguide with active region 102 designed to possess giant second-order nonlinearity χ⁽²⁾ for terahertz DFG. The laser waveguide is designed so that the THz frequency generated via the DFG process in the QCL active region is emitted into the InP device substrate 101 at a “Cherenkov” angle β_{c} given as:

$$cos ( {β}_{c} ) = \frac{{β}_{1} - {β}_{2}}{{k}_{THz}} = \frac{{n}_{g}}{{n}_{sub}} \qquad ( 1 )$$

where β₁ and β₂ are the propagation constants of the two mid-IR pumps, k_{THz} is the k-vector of the terahertz wave at frequency ω_{THz}=ω₁−ω₂ in the substrate, n_{g} is the group refractive index of the mid-IR pump modes, and n_{sub} the refractive index of the substrate at ω_{THz}.

Furthermore, as illustrated in FIG. 1A, quantum cascade laser 100 includes two grating sections 109A, 109B etched into separate sections of clad layer 104 and covered by metal 110. In one embodiment, grating sections 109A, 109B may be etched into separate sections of clad layer 105. In one embodiment, grating sections 109A, 109B are positioned along a length of the laser cavity 111 of laser 100 as showing FIG. 1A. In one embodiment, grating section 109A is designed to select a high (ω₁) mid-IR pump frequency and grating section 109B is designed to select a low (ω₂) pump frequency. Each grating section 109A, 109B in FIG. 1A can be independently biased to turn on or off the mid-infrared lasing and is separated by a gap etched through the heavily-doped top waveguide layer 104 to avoid electrical cross-talk (i.e., electrically isolated from one another) as discussed further below. In one embodiment, the length of grating sections 109A, 109B is approximately 0.05 mm to 50 mm. In one embodiment, the length of the gap between gating sections 109A, 109B is approximately 5 μm to 5,000 μm. Grating sections 109A, 109B may collectively or individually be referred to as grating sections 109 or grating section 109, respectively. While FIG. 1A illustrates two grating sections 109, quantum cascade laser 100 may include additional grating sections 109. The description herein regarding grating sections 109A, 109B applies to each of these additional grating sections.

The grating periods were selected to position the two mid-IR pump wavelengths as shown in FIG. 1B. That is, the periodicity of gratings 109 is used to determine the mid-infrared lasing frequencies. The frequency separation between ω₁ and ω₂ was chosen to provide THz emission at 3.5 THz, where the best performance of DFG-QCLs is currently achieved. In one embodiment, 2.7-mm-long ridge waveguide devices were fabricated with a 22 μm-wide-ridge widths. The lasers had two 1.2 mm-long grating sections separated by a 300 μm gap. Details of processing steps are discussed further below.

The lasers were operated by applying pulsed current above a lasing threshold to front section 109A. In this configuration, the grating in the front section 109A operates as distributed feedback grating (DFB), while the grating in the back section 109B operates as distributed Bragg reflector grating (DBR), as shown in FIG. 1A. In one embodiment, wavelength tuning is achieved by applying a DC bias below the lasing threshold either to back grating section 109B or to front grating section 109A. In the latter case, the DC bias was supplied through a bias tee. It is noted that while temperature tuning is employed to change mid-IR pump frequencies, other tuning mechanisms demonstrated in mid-IR QCLs, such as voltage tuning or optical tuning, may be employed as well.

Initial device testing was performed by applying pulsed current to front section 109A only without using any DC bias. Dual-color single-mode emission with 1/λ₁₌₁₀₅₆ cm⁻¹ and 1/λ₂₌₉₃₇ cm⁻¹ was observed for pump currents up to 1.6×Iₜₕ (1.6×threshold current), in excellent agreement with the grating design. At pump currents above 1.6×Iₜₕ, additional lasing modes appeared close to the center of the gain. The wavelength tuning performance of the device of the present invention was investigated at pulsed pump current of 1.3×Iₜₕ applied to front section 109A, well within the dynamic range of the single-mode pumps operation.

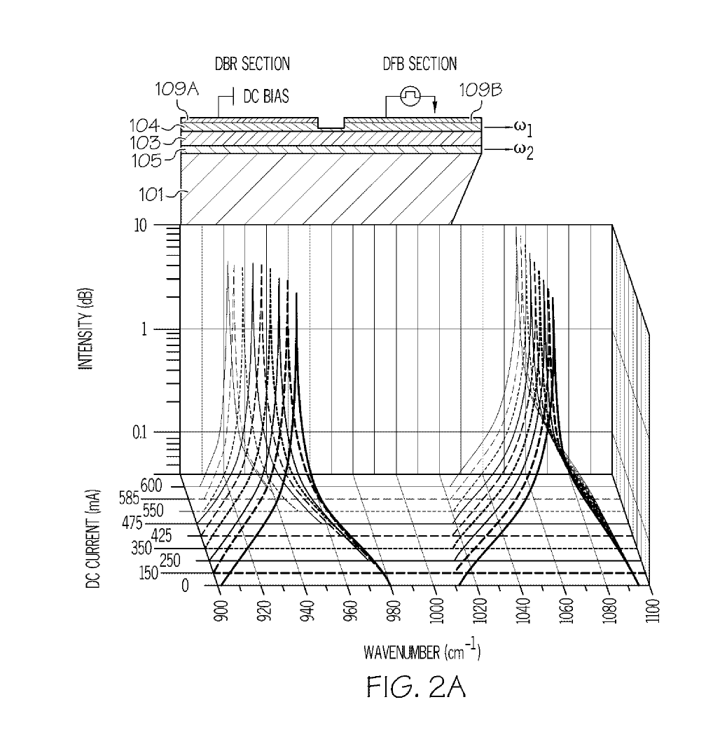

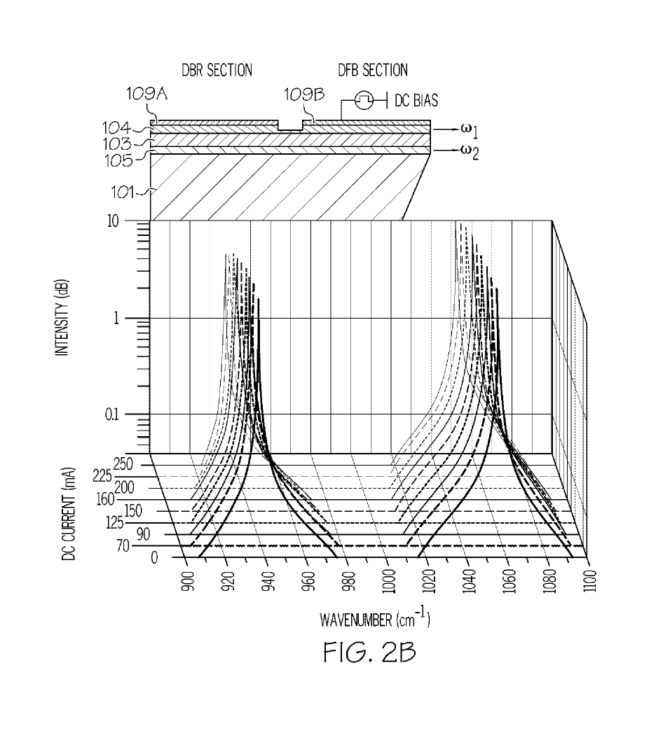

Wavelength tuning was achieved by applying DC bias either to the front or to the back section 109A, 109B, respectively. The tuning rate is expected to be proportional to the temperature change in the laser sections, which is in turn proportional to the dissipated electrical power. FIG. 2A illustrates the device configuration for low-frequency mid-IR pump tuning as well as the dual-color emission spectra for different DC bias currents applied to back section 109B in accordance with an embodiment of the present invention. FIG. 2B illustrates the device configuration for high-frequency mid-IR pump tuning, where back section 109B is unbiased while front section 109A is biased through a bias tree with both variable DC current (0 mA˜300 mA) and 1.3×Iₜₕ (2.4 A) current pulses in accordance with an embodiment of the present invention.

Referring to FIGS. 2A-2B, FIGS. 2A-2B show the tuning of mid-IR emission spectra as a function of DC current applied to laser sections 109A-109B. FIG. 2A displays the results when the DC bias is applied to back section 109B of the laser. As expected, the low frequency pump ω₂ shows significant red-shift due to increase of the effective modal refractive index in DBR section 109B with bias current. FIG. 2B displays the tuning of mid-IR pumps when DC bias is applied to front section 109A of the laser. In this case, the high frequency ω₁ shows significant red-shift.

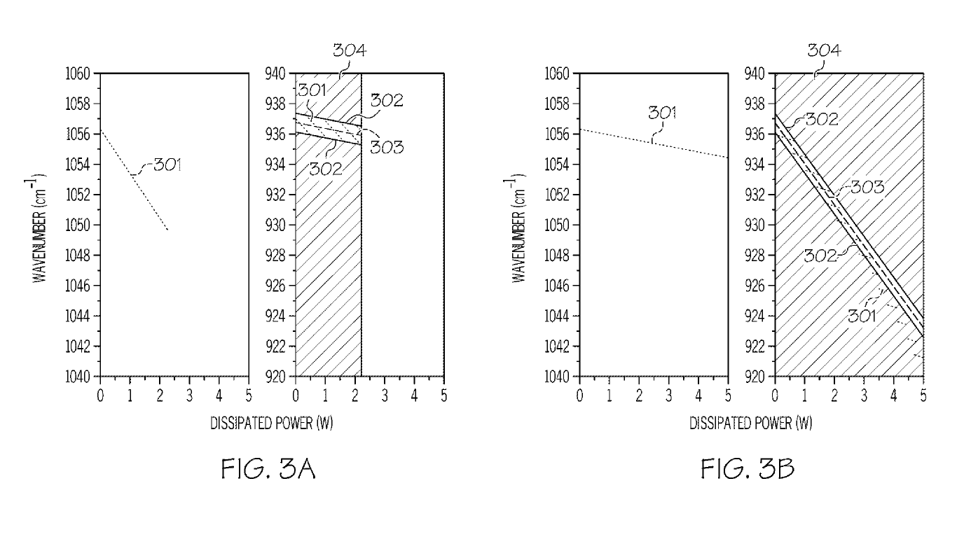

FIGS. 3A-3B show the details on the tuning behavior of the two mid-IR pump frequencies as a function of dissipated DC power, calculated as I_{DC}×V_{DC}, where I_{DC} and V_{DC} are the values of DC current and voltage applied to laser sections 109A-109B in accordance with an embodiment of the present invention. Elements 301 indicate the spectral positions of the measured mid-IR peaks. Lines 302 show the calculated position of the DFB mode (left panels) and the DBR reflection bandwidth (right panels) as a function of dissipated power. Lines 303 in both right panels indicate the mid-point of the DBR bandwidth. Lines 304 in the right panels in FIGS. 3A and 3B show the calculated laser cavity modes for DBR lasing as a function of DC bias currents.

Referring to FIGS. 3A-3B, as expected, the tuning rate is linearly proportional to the dissipated power applied to the tuning section. The spectral position of the high-frequency mid-IR mode w, is determined by the DFB grating in the laser cavity and it changes continuously with temperature. Over 6 cm⁻¹ (0.2 THz) of continuous w, tuning is observed when the DC bias is applied to front section 109A of the laser as shown in FIG. 3A. When the DC bias is applied to back section 109B of the device, very small tuning of ω₁ is still observed due to heat spreading to front DFB section 109A of the device (see FIG. 3B). The evolution of the spectral position of the low-frequency mid-IR mode is more complicated. Principally, it is determined by the position of the laser cavity modes within the high reflectivity band of the tunable DBR mirror, cf. FIG. 1A. The mid-IR pump ω₂ shows continuous tuning for approximately 0.5 cm⁻¹ and mode hopping to the next laser cavity mode spaced by approximately 0.9 cm⁻¹. This behavior can be well-explained by calculating the effective laser cavity length for the DBR mode of LDBR≈1.7 mm that gives mode spacing of 0.88 cm⁻¹ (26 GHz). The calculated dependence of the spectral positions of the DBR laser cavity modes as a function of DBR or DFB bias are shown as lines 304 in FIGS. 3A-3B. Details of these calculations are provided further below. Over 16 cm⁻¹ (0.4 THz) of ω₂ tuning is achieved when the DC bias is applied to back section 109B of the device as shown in FIG. 3B. When the bias is applied to front section 109A, the ω₂ pump mode shows zigzag tuning pattern as the effective laser cavity length changes (see FIG. 3A).

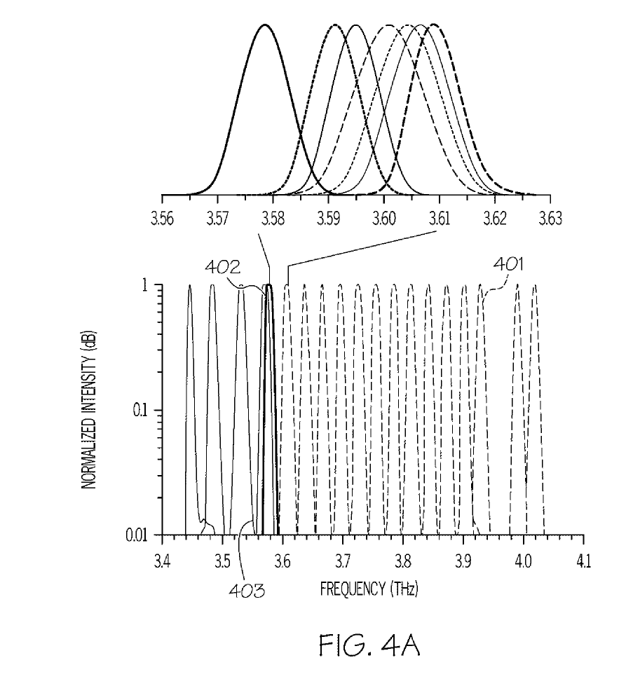

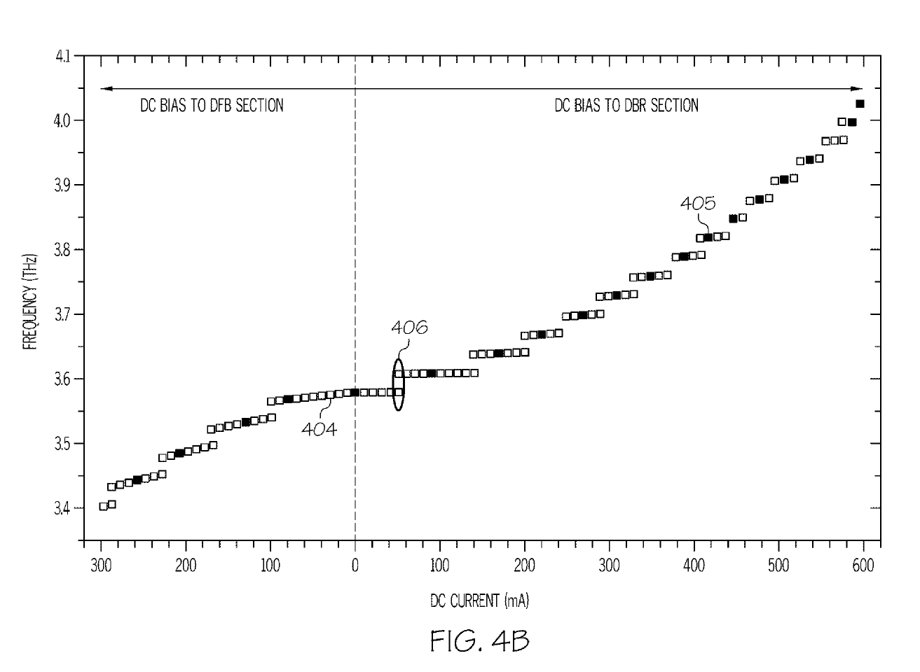

Spectra of tunable THz emission measured from the laser are shown in FIG. 4A in accordance with an embodiment of the present invention. FIG. 4A illustrates the THz spectra for various DC biases applied to DBR section 109B (line 401) or DFB section 109A (line 402). THz emission spectrum from a device without applying a DC bias is shown in line 403. The top inset of FIG. 4A illustrates the fine tuning of THz emission around the mode-hop point.

Referring to FIG. 4A, the linewidth of THz emission was measured to be 10 GHz in the whole tuning range, limited by the spectral resolution of the spectrometer (see below discussion). As the DC bias is applied to back section 109B of the laser, low frequency mid-IR pump ω2 is red shifted and the frequency separation between two mid-IR pumps increases leading to the blue shift of the THz DFG emission. When the DC bias is applied to front section 109A of the device, the frequency of mid-IR pump ω1 is reduced leading to the red shift of THz DFG emission. A total tuning range of 0.58 THz or over 15% of the THz center frequency is achieved in the devices of the present invention. Details of the tuning behavior of THz emission frequency are shown in FIG. 4B in accordance with an embodiment of the present invention.

Referring to FIG. 4B, elements 404 indicate THz emission frequency estimated from the peak spectral positions of the mid-IR pump frequencies shown in FIG. 3A. Elements 405 are the experimentally measured positions of THz emission frequencies as shown in FIG. 4A. As illustrated in FIG. 4B, the measured THz emission frequencies are in perfect agreement with expectations. Continuous single-mode tuning near the mode-hop points is achieved by adjusting DC bias voltages to both front and back sections 109A-109B of the laser. Demonstration of continuous tuning across the mode-hop region around 3.6 THz (see element 406 in FIG. 4B) is shown in the inset of FIG. 4A. To achieve the fine tuning, a second DC bias (dissipated power in the range of 60 to 250 mW) was applied to DFB section 109A to shift the DFB mode towards the long wavelength side while DBR section 109B was biased at a constant 370 mW DC power level. The THz peak power tuning curve is shown in FIG. 4B. For power measurements, the device was operated with 1.3×Iₜₕ=2.4 A current pulses (50 kHz, 50 ns) applied to front DFB section 109A. The THz power output is slightly increased at DFB DC bias power of 500 mW due to the associated increase of the high-frequency (ω₁) mid-IR pump intensity and then experiences gradual drop at high DC bias as mid-IR pump powers are reduced.

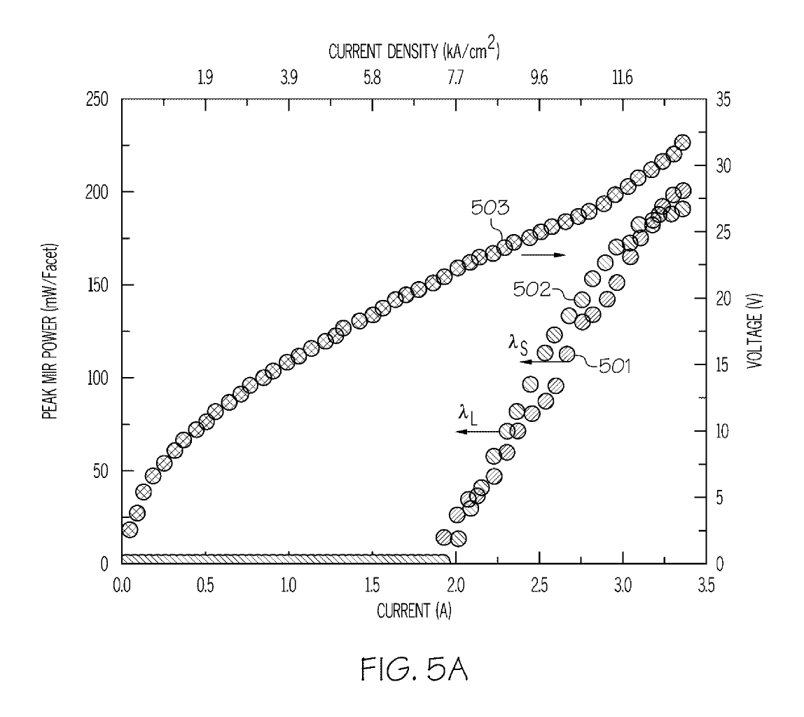

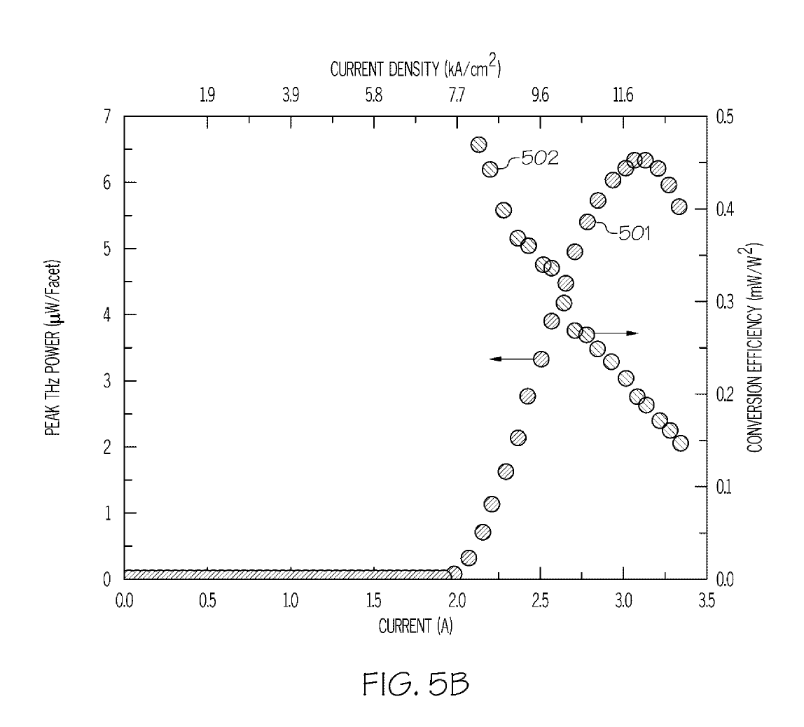

Light output-current and current-voltage characteristics of the mid-IR pumps of the device of the present invention measured without any DC bias are shown in FIG. 5A in accordance with an embodiment of the present invention. FIG. 5B illustrates the peak THz power and mid-IR-to-THz conversion efficiency measured under the same operating conditions as in FIG. 5A in accordance with an embodiment of the present invention. Referring to FIGS. 5A and 5B, elements 501, 502 and 503 indicate the short wavelength pump (λ_{S}) power, the long wavelength pump (λ_{L}) power and the applied voltage, respectively. For measurements shown in FIGS. 5A and 5B, the 1.2-mm-long and 22-μm-wide DFB section 109A was driven by pulse current with 50 kHz repetition frequency and 50 ns pulse width at 20° C., while the 0.3-mm-long gap and 1.2-mm-long DBR section 109B was unbiased. Furthermore, no collection efficiency was introduced to compensate THz power loss through the parabolic mirror setup, which leads to underestimation of THz power. The mid-IR power measurements were performed with estimated 100% collection efficiency. Maximum THz peak power was recorded as high as 6.3 μW with a mid-IR to THz nonlinear conversion efficiency of approximately 0.4 mWW⁻² near threshold and 0.2 mWW⁻² near the rollover point. The reduction of mid-IR to THz conversion efficiency is attributed to the reduction of optical nonlinearity due to change of the QCL bandstructure alignment at higher bias voltages.

The tuning range of 580 GHz is believed to be the largest tuning range obtained from a monolithic, electrically-pumped single-mode terahertz semiconductor source.

External cavity tuning of THz DFG-QCL chips and measurements of DFB THz DFG-QCL devices processed from the same wafer indicate that the THz tuning range of monolithic DFG-QCL sources can in principle be extended to span the entire 1-6 THz spectral range and beyond, limited only by the transparency window of InGaAs/AlInAs/InP materials and the rollover of THz DFG efficiency at low THz frequencies, as long as one finds a way to monolithically tune mid-IR pump or pumps over broad spectral range. Recent demonstrations of monolithic single-mode mid-IR QCL tuners based on sampled gratings with over 230 cm⁻¹ (nearly 7 THz) tuning range indicate that future monolithic THz DFG-QCL sources may achieve spectral coverage of the entire 1-6 THz frequency window and beyond. The devices of the present invention may also be integrated into arrays of lasers, similarly to that demonstrated in mid-IR, to provide continuous spectral coverage over broad THz spectral range.

As a result, it has been demonstrated herein that the THz DFG-QCL technology may enable mass-production of broadband monolithic semiconductor THz tuners with electrical emission frequency control. As the performance of THz DFG-QCL designs is being improved, compact electrically-controlled THz DFG-QCL tuners are expected to find applications in a wide variety of THz systems and are expected to dramatically reduce their size and complexity.

In one embodiment, laser heterostructure 100 was grown on a 350 μm thick semi-insulated InP substrate 101 using a metal organic vapor phase epitaxy system. A 200-nm-thick InGaAs layer 102 n-doped to 1×10¹⁸ cm⁻³ was grown on top of substrate 101 for lateral current extraction, followed by a 3.5-μm-thick lower InP cladding layer 105 n-doped to 1.5×10¹⁶ cm⁻³, a 4.2-μm-thick active region 103 made of two QCL stacks, and a 3.5-μm-thick upper InP cladding layer n-doped to 1.5×10¹⁶ cm⁻³. The growth was finalized with a 500-nm-thick InP outer cladding layer (combined with upper InP cladding layer to form cladding layer 104 as shown in FIGS. 1A and 1C) n-doped to 3.5×10¹⁸ cm⁻³ and a 20-nm-thick InGaAs contact layer 106 n-doped to 1×10¹⁹ cm⁻³.

In one embodiment, device fabrication started with removing the InGaAs contact layer 106 and reducing the thickness of the heavily doped InP outer cladding layer 104 from 500 nm to 100 nm to enhance the coupling between the laser mode and top surface gratings 109A-109B. Rectangular-shaped first order gratings with 50% duty cycle have been formed using electron-beam lithography. The length of both grating sections 109A-109B is 1.2 mm, resulting in a total cavity length of 2.7 mm including a 300 μm gap between sections 109A-109B. The 300 μm gap was etched through the remainder of the heavily doped InP outer cladding layer 104 to minimize electrical crosstalk between sections 109A-109B. The cross-talk resistance between grating sections 109A-109B was measured to be 700Ω at room temperature. This device configuration resulted in the two mid-IR pumps providing roughly equal amount of optical power near the rollover point.

Top DFB/DBR grating period was chosen to be 1.65 μm for the mid-IR pump wavelength of 10.6 μm and 1.48 μm for the mid-IR pump wavelength of 9.5 μm. Gratings 109A-109B were etched to 170 nm±10 nm depth and 22-μm-wide ridges with grating on top were then processed via dry etching. A 400-nm-thick SiN layer was deposited conformally and opened on top of the ridges for electrical contact. Metal contacts 110 (Ti/Au=20 nm/400 nm) for current injection and lateral extraction were then formed by evaporation and liftoff. Finally, the wafer was cleaved into 2.7-mm-long laser bars and the front facet of substrate 101 was polished at 30 degree angle for outcoupling of the Cherenkov radiation. Laser bars were then wire-bonded and mounted on copper blocks using indium paste.

1. Experimental Measurements

All optical measurements were performed under pulsed bias current with 50 kHz repetition rate and 50 ns pulse width at 20° C. Mid-IR optical power of each pump was measured using a calibrated thermopile detector. Optical filters were used to perform power measurements for each of the two mid-IR pumps. THz optical power was measured using a calibrated Golay cell detector and off-axis parabolic mirrors under N₂ purged condition to minimize water absorption. Mid-IR and THz spectra were measured using a Fourier-transform infrared spectrometer (FTIR) equipped with a deuterated L-alanine doped triglycine sulphate (DTGS) detector and a helium-cooled Si bolometer, respectively. The nominal FTIR spectral resolution is 0.2 cm⁻¹ for mid-IR and ˜0.25 cm⁻¹ for THz measurements.

The cavity mode spacing for the DBR laser is determined by the DBR laser cavity length LDBR that is made up of the length of front section 109A, the length of the gap, and the effective length of the DBR 109B (see FIG. 1A). The effective DBR length, L_{eff}, corresponds to the effective length of optical power penetration into grating 109B and is determined by the coupling constant, k. Assuming the effective refractive index of DBR section 109B is close to the group index of the Fabry-Perot (FP) QCLs, the effective grating length L_{eff} and coupling constant k can be estimated using the relation:

$${L}_{eff} = \frac{1}{2 k} ( tan h ( {k L}_{g} ) ,$$

where is the physical length of DBR grating 109B. Taking the value of the coupling constant to be 25 cm⁻¹ in accordance with simulations, one obtains ≈200 μm and the total DBR cavity length is L_{DBR}=1.7 mm. The modal spacing for the DBR laser can then be determined as Δ(1/λ)=1/(2n_{g}LDBR)≈0.88 cm⁻¹, where n_{g}≈3.35 was used. This result is an excellent agreement with the experimental measurement of 0.9 cm⁻¹.

2. Temperature Increase in the Laser Sections

The laser was operated with 50 ns pulsed current and no DC bias was applied to any of the laser sections 109A-109B. The data in FIGS. 3A-3B (discussed above) allows one to estimate the temperature tuning rate d(1/λ)/dT, in the device of the present invention to be −0.064 cm⁻¹K⁻¹ for the high mid-IR pump frequency (ω₁) and −0.056 cm⁻¹K⁻¹ for the low mid-IR pump frequency (ω₂). One can then use these coefficients to deduce the temperature change in the DFB and DBR sections 109A-109B for different applied DC powers shown in FIGS. 3A-3B. The maximum bias-induced temperature increase in the DFB and DBR sections 109A-109B is approximately 100° C. and 250° C., respectively.

3. Heat Diffusion Between the DFB and DBR Sections

FIGS. 3A-3B show the dependences of the mid-IR emission frequencies in the device of the present invention on the DC power applied either to DFB section 109A or to DBR section 109B. Nearly linear dependence of the frequency change on the applied DC power is observed in all cases. In particular, the tuning rate of the DFB mode was measured to be −2.94 cm⁻¹ W⁻¹ when the DC bias is applied to DFB section 109A and still to be −0.37 cm⁻¹ W⁻¹ when the DC bias was applied to DBR section 109B. Given the values of d(1/λ)/dT coefficients obtained above, one obtains a rate of the average temperature increase in DFB section 109A to be 45.9 K·W⁻¹ and 5.8 K·W⁻¹ when the DC power is applied to DFB section 109A and DBR section 109B, respectively. Since the device has a symmetric geometry, the same picture applies for temperature increase in DBR section 109B.

4. Laser Tuning Characteristics

The spectral position of the DFB lasing mode is determined by the Bragg wavelength of DFB grating 109A and one expects continuous tuning of the DFB lasing mode as the temperature of DFB section 109A is continuously changing, assuming mirror reflectivity is negligible. In contrast, the spectral position of the DBR mode is determined by the position of the laser cavity mode closest to the DBR mirror reflectivity peak and mode hopping behavior of the DBR laser emission is expected as the temperature of DBR section 109B is changed.

The relative shift of the spectral position of the DFB mode is given as,

$$\frac{Δ {v}_{B - DFB}}{{v}_{B - DFB}} = \frac{Δ {n}_{eff \_ DFB}}{{n}_{eff \_ DFB}} , \qquad ( 2 )$$

where n_{eff}_{_}_{DEB} (Δn_{eff}_{_}_{DEB}) is the value (change in value) of the effective refractive index of the laser mode in DFB section 109A.

The relative frequency shift of the peak of DBR mirror reflectivity (Δv_{B-DBR}/v_{B-DBR}) and the frequency change in the cavity mode position (Δv_{C}/v_{C}) as a function of the change of refractive indices in different sections of our device can be expressed as,

$$\begin{matrix}\frac{Δ {v}_{B - DBR}}{{v}_{B - DBR}} = \frac{Δ {n}_{eff \_ DBR}}{{n}_{eff \_ DBR}} , & ( 3 ) , \\ \frac{Δ {v}_{C}}{{v}_{C}} = \frac{Δ {n}_{eff \_ DFB} {L}_{DFB} + Δ {n}_{eff \_ gap} {L}_{gap} + Δ {n}_{eff \_ DBR} {L}_{eff}}{ {n}_{eff \_ DFB} {L}_{DFB} + {n}_{eff \_ gap} {L}_{gap} + {n}_{eff \_ DBR} {L}_{eff}} , & ( 4 )\end{matrix}$$

where n_{eff}_{_}_{DBR} (Δn_{eff}_{_}_{DBR}), n_{eff}_{_}_{gap} (Δn_{eff}_{_}_{gap}), and n_{eff}_{_}_{DEB} (Δn_{eff}_{_}_{DFB}) are the values (change in values) of the effective refractive indices of the long-wavelength laser mode ω₂ in DBR section 109B, in the gap between DFB and DBR sections 109A-109B, and in DFB section 109A, respectively, L_{DFB} is the length of DFB section 109A, L_{gap} is the length of the gap between DFB and DBR sections 109A-109B, and L_{eff} is the effective grating length for DBR section 109B defined earlier. In the analysis discussed herein, it was assumed that n_{eff}_{_}_{DBR}≈n_{eff}_{_}_{gap}≈n_{eff}_{_}_{DFB} for simplicity.

As DC bias on DFB section 109A increases, the effective refractive indices in different sections of the device of the present invention increase due to temperature rise. The process can approximately be expressed as,

Δn_{eff}_{_}_{DFB}≈S_{DFB}^{(DFB)}P_{dis}^{(DFB)}, (5)

Δn_{eff}_{_}_{DBR}≈S_{DBR}^{(DFB)}P_{dis}^{(DFB)}, (6)

Δn_{eff}_{_}_{gap}≈S_{gap}^{(DFB)}P_{dis}^{(DFB)}, (7)

where P_{dis}^{(DFB)} is the dissipated power applied to DFB section 109A, and S_{DFB}^{(DFB)}, S_{DBR}^{(DFB)}, and S_{gap}^{(DFB)} are the effective refractive index tuning coefficients in the DFB 109A, DBR 109B, and gap sections, respectively. The values of S_{DFB}^{(DFB)}=0.92×10⁻² W⁻¹ and S_{DBR}^{(DFB)}=0.12×10⁻² W⁻¹ are determined from the experimental data on modal tuning shown in FIG. 3A, using the relation:

$${n}_{eff} = \frac{π}{2 Λ} ,$$

where is the grating period and λ is the emission wavelength. Equations (4), (6), and (7) are then used to plot the position of the DBR laser cavity modes in the right panel in FIG. 3A. The contribution of Δn_{eff}_{_}_{gap} was ignored in the simulation due to its relatively short length though it can also be used as a fitting parameter.

Similarly, as DC bias on DBR section 109B increases, the effective refractive indices in various sections of the device change according to the expressions:

Δn_{eff}_{_}_{DBR}≈S_{DBR}^{(DBR)}P_{dis}^{(DBR)}, (8)

Δn_{eff}_{_}_{DFB}≈S_{DFB}^{(DRB)}P_{dis}^{(DBR)}, (9)

Δn_{eff}_{_}_{gap}≈S_{gap}^{(DBR)}P_{dis}^{(DBR)}, (10)

where P_{dis}^{(DFB)} is the dissipated power applied to DFB section 109A, and S_{DFB}^{(DFB)}, S_{DBR}^{(DFB)}, and S_{gap}^{(DFB)} are the effective refractive index tuning coefficients in the DFB 109A, DBR 109B, and gap sections, respectively. The values of S_{DFB}^{(DBR)}=0.92×10⁻² W⁻¹ and S_{DBR}^{(DBR)}=0.12×10⁻² W⁻¹ are determined from the experimental data on modal tuning shown in FIG. 3B as described above. Equations (4), (8), and (9) are then used to plot the position of the DBR laser cavity modes in the right panel in FIG. 3B. The contribution of Δn_{eff}_{_}_{gap} was ignored in the simulation for the same reason noted above.

As a result of designing a quantum cascade laser using the principles of the present invention discussed above, an electrically pumped and completely monolithic (i.e., it requires no moving parts or external components) THz DFG-QCL tuner can be achieved. This is in contrast to competing semiconductor THz source technologies of similar size, such as photomixcrs, photoconductive switches, external cavity THz QCLs and external cavity THz DFG-QCLs. An all-monolithic construction is cheaper to manufacture, rugged, compact, simpler to design and operate, and enables seamless integration in larger system solutions.

The present invention can operate in a spectral region (0.5-10 THz) inaccessible by electronic mixers/multipliers/photomixers (maximum 2.5 THz). While photoconductive switches and optical parametric oscillators (OPOs) can operate over a wide spectral range, they are prohibitively large, expensive to manufacture, complex to operate and provide only broadband output with limited tuning. However, the present invention is extremely compact, cost-effective, and can generate tunable, single-frequency THz radiation that is highly desired for frequency-domain spectroscopic applications. Additionally, the present invention can operate at room-temperature which is a significant advantage compared to traditional THz QCL systems or p-Ge lasers that require cryogenic cooling.

An alternative embodiment of the present invention is implementing a source with two or more feedback grating sections 109 (FIG. 1A) for multi-wavelength mid-infrared lasing and multi-wavelength tunable terahertz generation.

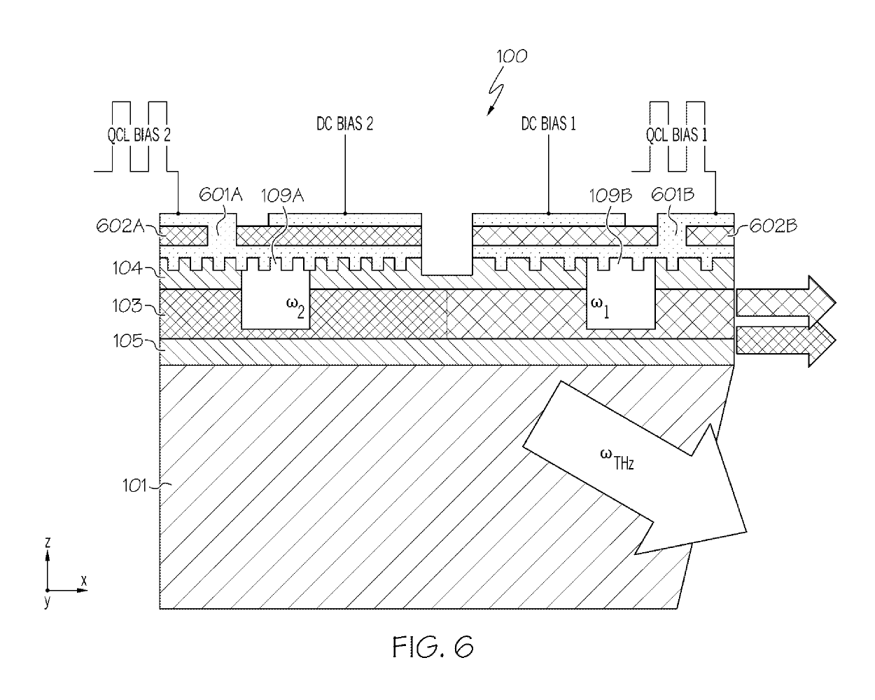

A further embodiment of the present invention is implementing a device that decouples the DC current required for mid-infrared tuning from the electrical bias required to activate/quench the lasing wavelength. One such configuration is shown in FIG. 6 which depicts quantum cascade laser 100 of FIG. 1 being modified by including an independently controlled tuning element 601A-601B positioned on each grating section 109A-109B, respectively, along with an insulating layer 602A-602B to separate the DC bias sections (labeled as “DC Bias 2” and “DC Bias 1” in FIG. 6) from grating sections 109A-109B, respectively, in accordance with an embodiment of the present invention. The quantum cascade laser (QCL) bias (labeled as “QCL Bias 1” and “QCL Bias 2”) discussed above is also shown in FIG. 6. Tuning elements 601A-601B may collectively or individually be referred to as tuning elements 601 or tuning element 601, respectively. Tuning elements 601 can be monolithically fabricated alongside grating elements 109, or comprise of external elements affixed to each grating section 109. Tuning elements 601 are electrically isolated from one another and from the rest of the device. The temperature of each tuning element 601 can be independently controlled with a DC current, where the DC current applied to tuning elements 601 is independent of an electrical bias required to activate and quench the mid-infrared lasing. Alternatively, the temperature of tuning element 601 can be independently changed via optically induced heating from an external laser source. The change in the tuning element temperature causes a shift in the mid-infrared lasing wavelength and results in terahertz tuning.

In another embodiment of the present invention, a tunable terahertz source with broad spectral coverage includes an array of monolithically tunable terahertz difference-frequency generation quantum cascade lasers. Each laser in the array operates and tunes in a specific terahertz spectral band.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method comprising:
generating terahertz radiation with a quantum cascade laser via infrared difference-frequency generation,
wherein the quantum cascade laser is simultaneously operating at multiple mid-infrared frequencies, wherein the quantum cascade laser is designed with a modal phase matching scheme or a Cherenkov phase matching scheme to extract the terahertz radiation,
wherein the quantum cascade laser comprises:
a substrate;
a lower cladding semiconducting layer positioned above said substrate;
an active region layer with optical nonlinearity, wherein said active region layer is positioned on said lower cladding semiconductor layer, wherein said active region layer is arranged as a multiple quantum well structure with optical nonlinearity for terahertz generation;
an upper cladding semiconducting layer positioned on said active region layer; and
two or more mid-infrared feedback gratings etched into spatially separated sections of said lower or upper cladding semiconducting layers, wherein said two or more mid-infrared feedback gratings are positioned along a length of a laser cavity, wherein mid-infrared lasing frequencies are determined by a periodicity of said two or more mid-infrared feedback gratings, wherein said two or more mid-infrared feedback gratings are electrically isolated from one another and are biased independently to turn on or off said mid-infrared lasing, wherein tuning is achieved by changing a refractive index of one or all of said two or more mid-infrared feedback gratings via a DC current bias thereby causing a shift in a mid-infrared lasing frequency, wherein a change in said mid-infrared lasing frequency translates to tuning of terahertz radiation.

2. The method as recited in claim 1, wherein periods of said two or more mid-infrared feedback gratings spectrally determine mid-infrared pump wavelengths.

3. The method as recited in claim 1, wherein each of said two or more mid-infrared feedback gratings is independently electrically biased to activate or quench said mid-infrared lasing.

4. The method as recited in claim 1, wherein red or blue shifted wavelength tuning of said mid-infrared lasing frequency is controlled by an applied DC current.

5. The method as recited in claim 4, wherein said applied DC current is combined with a quantum cascade laser bias.

6. The method as recited in claim 1, wherein said two or more mid-infrared feedback gratings have a length of approximately 0.05 mm to 50 mm.

7. The method as recited in claim 1, wherein a gap between each of said two or more mid-infrared feedback gratings is etched into said upper cladding semiconducting layer to electrically isolate and minimize crosstalk between each of said two or more mid-infrared feedback gratings.

8. The method as recited in claim 7, wherein said gap between each of said two or more mid-infrared feedback gratings has a length of approximately 5 μm to 5,000 μm.

9. The method as recited in claim 1, further comprising: tuning elements monolithically fabricated alongside said two or more mid-infrared feedback gratings or comprise external elements affixed to each of said two or more mid-infrared feedback gratings, wherein said tuning elements are electrically isolated from one another, wherein a temperature of each of said tuning elements is independently controlled with a DC current, wherein said DC current applied to said tuning elements is independent of an electrical bias required to activate and quench said mid-infrared lasing.

10. The method as recited in claim 1, wherein the quantum cascade laser further comprises an array of said quantum cascade lasers, wherein each of said quantum cascade lasers is designed to emit and tune over a specific terahertz spectral range.

11. A terahertz difference-frequency generation quantum cascade laser source, comprising:
a quantum cascade laser comprising:
a substrate;
a lower cladding semiconducting layer positioned above said substrate;
an active region layer with optical nonlinearity, wherein said active region layer is 6 positioned on said lower cladding semiconductor layer, wherein said active region layer is arranged as a multiple quantum well structure with optical nonlinearity for terahertz generation;
an upper cladding semiconducting layer positioned on said active region layer; and
two or more mid-infrared feedback gratings etched into spatially separated sections of said lower or upper cladding semiconducting layers, wherein said two or more mid-infrared feedback gratings are positioned along a length of a laser cavity, wherein mid-infrared lasing frequencies are determined by a periodicity of said two or more mid-infrared feedback gratings, wherein said two or more mid-infrared feedback gratings are electrically isolated from one another and are biased independently to turn on or off said mid-infrared lasing, wherein tuning is achieved by changing a refractive index of one or all of said two or more mid-infrared feedback gratings via a DC current bias thereby causing a shift in a mid-infrared lasing frequency, wherein a change in said mid-infrared lasing frequency translates to tuning of terahertz radiation; and
wherein said quantum cascade laser generates terahertz radiation via infrared difference-frequency generation and simultaneously operates at multiple mid-infrared frequencies, wherein said quantum cascade laser is designed with a modal phase matching scheme or a Cherenkov phase matching scheme to extract terahertz radiation.

12. The terahertz difference-frequency generation quantum cascade laser source as recited in claim 11, wherein periods of said two or more mid-infrared feedback gratings spectrally determine mid-infrared pump wavelengths.

13. The terahertz difference-frequency generation quantum cascade laser source as recited in claim 11, wherein each of said two or more mid-infrared feedback gratings is independently electrically biased to activate or quench said mid-infrared lasing.

14. The terahertz difference-frequency generation quantum cascade laser source as recited in claim 11, wherein red or blue shifted wavelength tuning of said mid-infrared lasing frequency is controlled by an applied DC current.

15. The terahertz difference-frequency generation quantum cascade laser source as recited in claim 14, wherein said applied DC current is combined with a quantum cascade laser bias.

16. The terahertz difference-frequency generation quantum cascade laser source as recited in claim 11, wherein said two or more mid-infrared feedback gratings have a length of approximately 0.05 mm to 50 mm.

17. The terahertz difference-frequency generation quantum cascade laser source as recited in claim 11, wherein a gap between each of said two or more mid-infrared feedback gratings is etched into said upper cladding semiconducting layer to electrically isolate and minimize crosstalk between each of said two or more mid-infrared feedback gratings.

18. The terahertz difference-frequency generation quantum cascade laser source as recited in claim 17, wherein said gap between each of said two or more mid-infrared feedback gratings has a length of approximately 5 μm to 5,000 μm.

19. The terahertz difference-frequency generation quantum cascade laser source as recited in claim 11, further comprising: tuning elements monolithically fabricated alongside said two or more mid-infrared feedback gratings or comprise external elements affixed to each of said two or more mid-infrared feedback gratings, wherein said tuning elements are electrically isolated from one another, wherein a temperature of each of said tuning elements is independently controlled with a DC current, wherein said DC current applied to said tuning elements is independent of an electrical bias required to activate and quench said mid-infrared lasing.

20. The terahertz difference-frequency generation quantum cascade laser source as recited in claim 11, further comprises an array of said quantum cascade lasers, wherein each of said quantum cascade lasers is designed to emit and tune over a specific terahertz spectral range.
